(19) United States
(12) Patent Application Publication
(10) Pub. No.: US 2023/0115922 A1
(43) Pub. Date: Apr. 13, 2023

(54) METHOD FOR MONITORING SUBSTRATE, METHOD FOR FABRICATING SEMICONDUCTOR DEVICE USING THE SAME, AND SUBSTRATE PROCESS SYSTEM USING THE SAME

(71) Applicant: SAMSUNG ELECTRONICS CO., LTD., Suwon-si (KR)

(72) Inventors: Yong In LEE, Seoul (KR); In Hwa BAEK, Hwaseong-si (KR); Se-Hoon JANG, Hwaseong-si (KR); Dong Gap SHIN, Seoul (KR); Young Ho KIM, Gwangju (KR); Seung Dae SEOK, Seongnam-si (KR); Si Woong WOO, Hwaseong-si (KR); Jun Gyu LEE, Suwon-si (KR)

(21) Appl. No.: 17/749,436

(22) Filed: May 20, 2022

(30) Foreign Application Priority Data
Oct. 7, 2021 (KR) 10-2021-0133106

(51) Int. Cl. H01J 37/32

(52) U.S. Cl. CPC H01J 37/32972; H01J 37/32862

(57) ABSTRACT

A method for fabricating a semiconductor device includes loading a substrate into a process chamber, processing the substrate in the process chamber, using a plasma generated inside the process chamber, receiving a plasma light emitted from the plasma, selecting a target light from the plasma light, such that the target light is related to a surface condition of the substrate, and analyzing an intensity of the target light over time to monitor the surface condition of the substrate.

### CROSS-REFERENCE TO RELATED APPLICATION

This application claims priority to Korean Patent Application No. 10-2021-0133106, filed on Oct. 7, 2021, and all the benefits accruing therefrom under 35 U.S.C. § 119, the disclosure of which is incorporated herein by reference in its entirety.

### BACKGROUND

### 1. Field

Embodiments relate to a method for monitoring a substrate, a method for fabricating a semiconductor device using the same, and a substrate processing system using the same. More specifically, embodiments relate to a method for monitoring a substrate using optical emission spectroscopy (OES), a method for fabricating a semiconductor device using the same, and a substrate processing system using the same.

### 2. Description of the Related Art

A semiconductor device may be formed by various semiconductor fabricating processes, e.g., an etching process, a vapor deposition process, an ashing process, and a cleaning process. In particular, in recent years, a plasma process of accelerating a desired chemical reaction (e.g., vapor deposition or etching) using plasma has been variously used. For example, optical emission spectrometry (OES) may be used to optically detect the presence or absence of abnormalities in the plasma process. The optical emission spectroscopy may be performed in a non-destructive manner outside the process chamber without an insertion of a probe or the like.

### SUMMARY

According to an aspect of embodiments, there is provided a method for fabricating a semiconductor device, including loading a substrate into a process chamber, processing the substrate, using a plasma generated inside the process chamber, receiving a plasma light emitted from the plasma, selecting a target light related to a surface condition of the substrate from the plasma light, and analyzing intensity of the target light over time to monitor the surface condition of the substrate.

According to an aspect of embodiments, there is provided a method for fabricating a semiconductor device, including loading a substrate into a process chamber, performing a surface treatment on the substrate, using a plasma generated inside the process chamber, receiving a plasma light emitted from the plasma, selecting a first target light related to a bonding strength of the substrate from the plasma light, and measuring intensity of the first target light over time to monitor the bonding strength of the substrate, and performing a bonding process on the surface-treated substrate.

According to an aspect of embodiments, there is provided a method for fabricating a semiconductor device, including providing a substrate, and performing a plasma process on the substrate using a substrate processing system, wherein the substrate processing system includes a process chamber into which the substrate is loaded, a spectrometer which receives a plasma light generated from a plasma, and an analyzer which receives data about the plasma light from the spectrometer to monitor a surface condition of the substrate, wherein the analyzer selects a target light related to the surface condition of the substrate from the data about the plasma light, and analyzes intensity of the target light over time to monitor the surface condition of the substrate.

### BRIEF DESCRIPTION OF THE DRAWINGS

Features will become apparent to those of skill in the art by describing in detail exemplary embodiments with reference to the attached drawings, in which:

FIG. 1 is a schematic diagram of a substrate processing system according to some embodiments.

FIG. 2 is a schematic detailed diagram of a spectrometer of FIG. 1.

FIGS. 3 to 7 are diagrams for explaining a method for monitoring a substrate according to some embodiments.

FIGS. 8A to 8D are exemplary intermediate stage diagrams for explaining a bonding process on the substrate.

FIGS. 9 to 11 are diagrams for explaining a method for monitoring a substrate according to some embodiments.

FIGS. 12 and 13 are diagrams for explaining a method for monitoring a substrate according to some embodiments.

FIG. 14 is an exemplary diagram for explaining the substrate processing system according to some embodiments.

FIGS. 15 to 16C are diagrams for explaining a method for fabricating a semiconductor device using the method for monitoring a substrate according to some embodiments.

### DETAILED DESCRIPTION

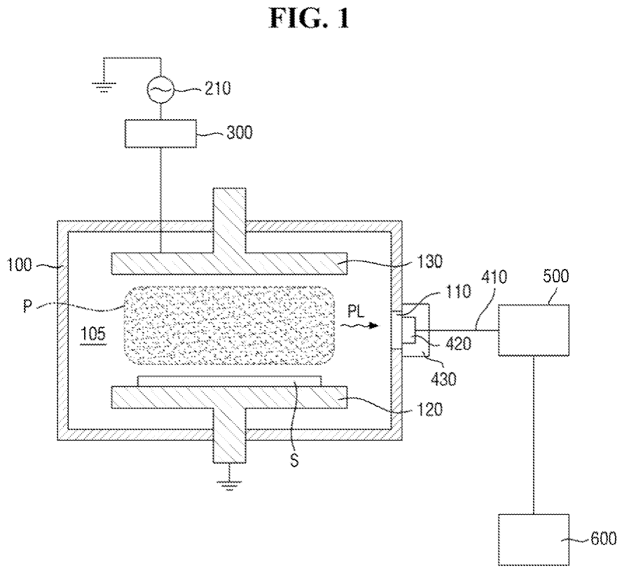

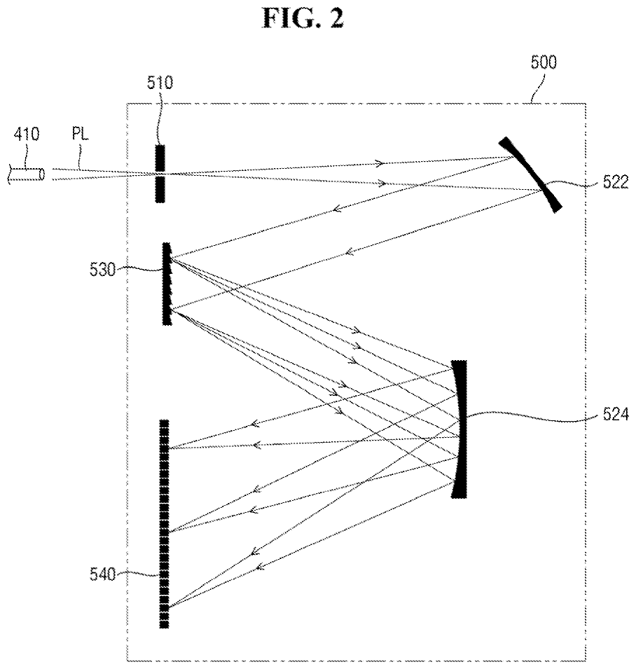

Hereinafter, a substrate processing system according to exemplary embodiments will be described referring to FIGS. 1 and 2.

A substrate processing system according to some embodiments may analyze a plasma condition in the process chamber, using optical emission spectroscopy (OES), which is an optical diagnostic technique for the plasma process. For example, a substrate processed by the substrate processing system according to some embodiments may be a semiconductor substrate for fabricating a semiconductor device, a glass substrate for fabricating a flat plate display element, and the like. For example, the treatment process performed by the substrate processing system according to some embodiments may be an etching process, a deposition process, an ashing process, and/or a cleaning process.

FIG. 1 is an exemplary diagram for explaining the substrate processing system according to some embodiments. FIG. 2 is an exemplary diagram for explaining a spectrometer of FIG. 1.

Referring to FIGS. 1 and 2, the substrate processing system according to some embodiments may include a process chamber 100, a stage 120, a shower head 130, a power supply unit 210, a matching unit 300, a spectrometer 500, and an analyzer 600.

The process chamber 100 may provide an internal space 105 for performing a treatment process on a substrate S (e.g., a wafer). Plasma P is generated in the internal space 105, and the plasma process on the substrate S may be performed. The process chamber 100 may be provided in a closed structure so that the internal space 105 may be maintained in a vacuum (e.g., about 1 torr or less). The process chamber 100 may have various shapes, e.g., a hollow hexahedron or a hollow cylinder. The process chamber 100 may include, e.g., at least one of a metal and an insulator.

The process chamber 100 may include a window 110. The number and arrangement of windows 110 are merely exemplary and are not limited to those shown. The window 110 may receive a plasma light PL generated from the plasma P. For example, the window 110 may include a material capable of transmitting the plasma light PL, e.g., glass or quartz.

The stage 120 may be placed in the internal space 105 of the process chamber 100 to support the substrate S. For example, the stage 120 may be placed at a lower portion the internal space 105. The substrate S may be loaded onto the stage 120. As an example, the stage 120 may be an electrostatic chuck that fixes the substrate S by electrostatic force. In some embodiments, the stage 120 may include a heater for heating the substrate S to a temperature suitable for the plasma process.

The shower head 130 may be placed in the internal space 105 of the process chamber 100, and may supply the process gas into the process chamber 100. For example, the shower head 130 may be placed at an upper portion of the internal space 105, e.g., the stage 120 and shower head 130 may be at opposite sides of the process chamber 100. The shower head 130 may face the stage 120. As a result, the shower head 130 may supply the process gas onto the substrate S loaded on the stage 120. The process gas may include, e.g., at least one of CF₄, C₄F₆, C₄F₈, COS, CHF₃, HBr, SiO₄, O₂, N₂, H₂, NF₃, SF₆, He, Xe or Ar.

The power supply unit 210 may form an electric field for generating or controlling plasma P inside the process chamber 100. As an example, the power supply unit 210 may be, e.g., electrically, connected to the shower head 130, and the stage 120 may be grounded. The power supply unit 210 may supply electric power to the shower head 130 to form an electric field between the stage 120 and the shower head 130. In the following description, the stage 120 may also be referred to as a lower electrode, and the shower head 130 may also be referred to as an upper electrode. When the electric power is applied from the power supply unit 210 to the lower electrode (e.g., the stage 120) or the upper electrode (e.g., the shower head 130), an electric field may be formed by a potential difference between the lower electrode and the upper electrode. Therefore, the plasma P may be generated from the process gas supplied into the process chamber 100 by the shower head 130. The number and arrangement of the power supply units 210 are merely exemplary and are not limited to those shown.

In some embodiments, the power supply unit 210 may be an alternating current (RF) power supply. As an example, the power supply unit 210 may be an RF source power supplier which applies an RF source power. As another example, the power supply unit 210 may be an RF bias power supplier that applies an RF bias power. In some other embodiments, the power supply unit 210 may be a direct current (DC) power supply.

The matching unit 300, i.e., a matcher, may minimize the loss of electric power generated from the power supply unit 210. As an example, the matching unit 300 may be interposed between the power supply unit 210 and the upper electrode (e.g., the shower head 130) to improve the transfer efficiency of the electric power applied to the upper electrode. In some embodiments, the matching unit 300 may be placed to correspond to the number of power supply units 210 and be connected to each of them. In some other embodiments, the matching unit 300 may be omitted.

The spectrometer 500 may receive the plasma light PL transmitted through the window 110. For example, an optical fiber 410 placed adjacent to the window 110 may be provided. The optical fiber 410 may receive the plasma light PL transmitted through the window 110 and transfer it to the spectrometer 500.

In some embodiments, a filter 420 may be provided between the window 110 and the optical fiber 410. The filter 420 may filter at least a part of the plasma light PL received by the optical fiber 410. As an example, the filter 420 may remove a noise component (e.g., noise or the like amplified by the reflection between the shower head 130 and the substrate S) generated inside the process chamber 100, by filtering at least a part of a TE (Transverse Electric) mode component in the plasma light PL received by the optical fiber 410.

In some embodiments, a collimator 430 may be provided between the window 110 and the optical fiber 410. The collimator 430 may be placed outside the window 110. The collimator 430 may be, e.g., a collimator lens. The collimator 430 may collimate the plasma light PL received by the optical fiber 410.

The spectrometer 500 may disperse and detect the plasma light PL transferred from the optical fiber 410. In an example, as shown in FIG. 2, the spectrometer 500 may include an inlet slit 510, imaging mirrors 522 and 524, a diffraction grating 530, and an array detector 540.

The plasma light PL transferred from the optical fiber 410 may be incident on the spectrometer 500 through the inlet slit 510. The imaging mirrors 522 and 524 may collect the plasma light PL spreading from the inlet slit 510 to form an image on the array detector 540. The number and arrangement of the imaging mirrors 522 and 524 are merely exemplary and are not limited to those shown. The array detector 540 may be, e.g., a CCD (Charged Coupled Device). The diffraction grating 530 may be placed in the middle of an optical path from the inlet slit 510 to the array detector 540, and may disperse the plasma light PL according to the wavelength. The diffraction grating 530 may be, e.g., a reflection type diffraction grating. As a result, the lights dispersed for each wavelength from the plasma light PL may form an image at different locations of the array detector 540. The spectrometer 500 shown in FIG. 2 is merely exemplary and the spectrometer 500 may be provided in various other structures for performing the optical emission spectroscopy.

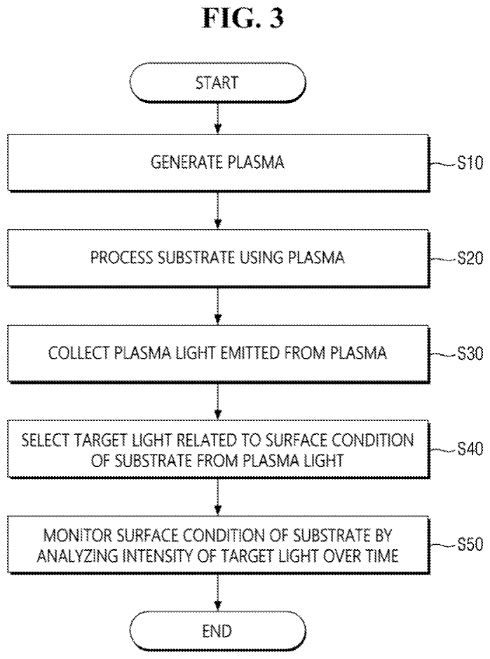

The analyzer 600 may receive data about the plasma light PL from the spectrometer 500 and may analyze the data to monitor the substrate S. For example, the data of the plasma optical PL provided through the array detector 540 may be transferred to the analyzer 600, and the analyzer 600 may analyze the transferred data and monitor the processing condition of the substrate S using the plasma P. The method for monitoring the substrate S by the analyzer 600 will be described more specifically in the description of FIGS. 3 to 13.

The analyzer 600 may include software (e.g., an analysis program) for monitoring the substrate S from the data transferred from the spectrometer 500. The analyzer 600 may include, e.g., at least one of a personal computer (PC), a desktop computer, a laptop computer, a computer workstation, a tablet PC, a server, a mobile computing device, and combinations thereof. The mobile computing device may be implemented as, e.g., a mobile phone, a smartphone, an enterprise digital assistant (EDA), a digital still camera, a digital video camera, a PMP (portable multimedia player), a PND (personal navigation device or a portable navigation device), a mobile internet device (MID), a wearable computer, an Internet of Things (IoT) device, an Internet of Everything (IOE) device, an e-book or the like. Hereinafter, a method for monitoring a substrate according to an exemplary embodiment will be described referring to FIGS. 1 to 13. FIGS. 3 to 7 are diagrams for explaining the method for monitoring the substrate S according to some embodiments. For the convenience of explanation, repeated parts of contents explained above using FIGS. 1 and 2 will be only briefly described or omitted.

Referring to FIGS. 1 to 3, the plasma P is first generated in the process chamber 100 (S10). For example, the process gas may be supplied from the shower head 130 into the process chamber 100. Subsequently, the power supply unit 210 may form an electric field between the lower electrode (e.g., the stage 120) and the upper electrode (e.g., the shower head 130), thereby generating the plasma P from the process gas.

Subsequently, the substrate S is processed using the plasma P (S20). For example, processing of the substrate S may include performing an etching process, a vapor deposition process, an ashing process, a cleaning process, and the like. In some embodiments, processing of the substrate S may include performing a surface treatment on the substrate S.

Subsequently, the plasma light PL emitted from the plasma P is received (S30).

For example, the plasma light PL may be received by the spectrometer 500. The spectrometer 500 may disperse and detect the plasma light PL. Therefore, the spectrometer 500 may provide data about the plasma light PL.

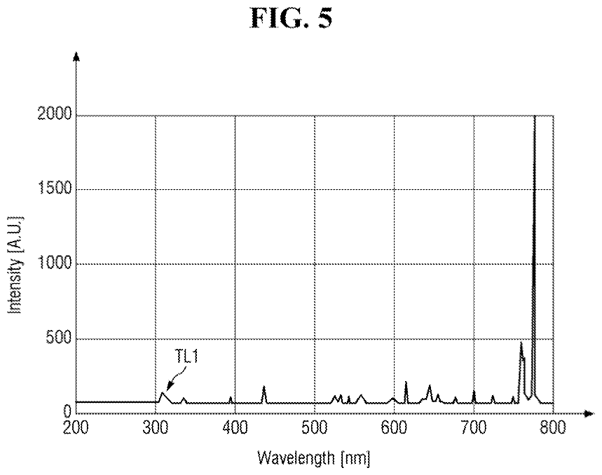

In some embodiments, the emission spectrum may be generated from the received plasma light PL. As an example, the emission spectrum of FIG. 5 may be provided from the spectrometer 500. The emission spectrum may be provided as a graph by measuring the intensity according to the wavelength from the dispersed plasma light.

In some embodiments, the emission spectrum may include a full spectrum of a predetermined wavelength range. As an example, as shown in FIG. 5, a full spectrum in which the intensity is measured in the continuous wavelength range from 200 nm to 800 nm may be provided.

Subsequently, a target light related to the surface condition of the substrate S is selected from the plasma light PL (S40). For example, the selection (S40) of the target light may be performed by the analyzer 600. The analyzer 600 may receive data about the plasma light PL from the spectrometer 500, and may select the target light from the data. For example, the light of a predetermined wavelength range may be selected as the target light from the emission spectrum.

The target light may be emitted light of a chemical species related, e.g., corresponding, to the surface condition of the substrate S. For example, the light of a wavelength corresponding to a predetermined chemical species related to, e.g., correlated to or resultant from, the surface condition of the substrate S, e.g., a surface condition during or after processing the substrate S, may be selected from the emission spectrum.

In some embodiments, the target light may be emitted light of a chemical species related to the bonding strength of the substrate S, e.g., a specific wavelength having the highest correlation with bonding strength may be identified and selected from the emission spectrum. The bonding strength of the substrate S means the bonding strength of the substrate S to be bonded in the bonding process on the substrate S. For example, the bonding process may include an oxide bonding type, a copper-copper bonding type, a copper-oxide hybrid bonding type, and the like.

In some other embodiments, the target light may be emitted light of a chemical species associated with a contamination level of the substrate S. The contamination level of the substrate S may be a contamination level caused by contaminants generated when the substrate S is treated using the plasma P (e.g., metal particle contaminants caused by plasma treatment during copper-to-copper bonding).

Subsequently, the intensity of the target light over time is analyzed, and the surface condition of the substrate S is monitored (S50). Monitoring of the surface condition of the substrate S (S50) may be performed by, e.g., the analyzer 600. The analyzer 600 may receive the data about the plasma light PL from the spectrometer 500 and analyze the data to monitor the substrate S.

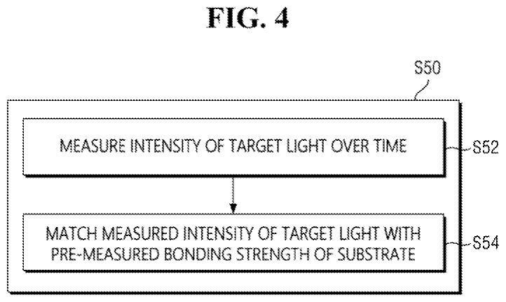

Referring to FIGS. 3 and 4, in the method for monitoring the substrate S according to some embodiments, the monitoring (S50) of the surface condition of the substrate S may include measuring the intensity of the target light over time (S52), and matching the measured intensity of the target light with a pre-measured bonding strength of the substrate S (S54).

For example, the first target light TL1 related to the bonding strength of the substrate S may be selected from the emission spectrum of FIG. 5. That is, the first target light TL1 may be emitted light of a chemical species related to the bonding strength of the substrate S.

In some embodiments, the first target light TL1 may be the emitted light of hydroxyl radical (OH) selected from the plasma light PL. For example, light having a wavelength of about 309 nm may be selected as the first target light TL1 from the emission spectrum of FIG. 5. However, other emitted light related to the bonding strength of the substrate S may be selected as the first target light TL1. Further, a plurality of emitted lights having different wavelengths may be selected as the first target light TL1.

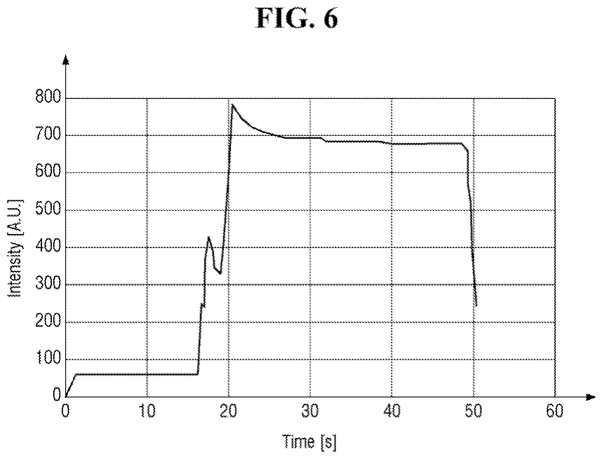

Subsequently, the intensity of the first target light TL1 over time may be measured (S52). For example, the intensity of the first target light TL1 over time may be measured to provide the graph of FIG. 6.

Next, the measured intensity of the first target light TL1 may be matched with the pre-measured bonding strength of the substrate S (S54). The bonding strength of the substrate S may be measured in advance and provided as data.

For example, the bonding strength of the substrate S may be measured in advance by a DCB (Double Cantilever Beam) method. The DCB method is a method of calculating, e.g., measuring or determining, a bonding strength of bonded substrates by measuring a distance of bonded surfaces of the bonded substrates that are separated by inserting a blade therebetween, e.g., via use of the thickness of the blade, the mechanical properties of the substrates, the thickness of the substrates, and the like. However, this is merely an example, e.g., the bonding strength of the substrate S may be measured in advance by various other methods.

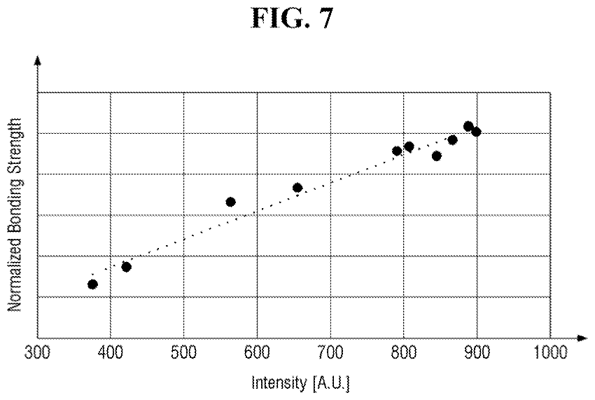

For example, the graph of FIG. 7 may be provided as data reflecting the bonding strength of the substrate S, e.g., the intensity in FIG. 7 refers to the intensity of the first target light TL1. The measured intensity of the first target light TL1 may be matched with the bonding strength of the substrate S through the graph of FIG. 7. In some embodiments, as shown in FIG. 7, the intensity of the first target light TL1 may have a linear correlation with the bonding strength of the substrate S. For example, as illustrated in FIG. 7, as the intensity of the first target light TL1 increases, the bonding strength of the substrate S may increase.

As the intensity of the first target light TL1 measured over time is matched with the bonding strength of the substrate S measured in advance, the surface condition of the substrate S may be monitored in real-time. For example, the bonding strength of the substrate S may be calculated in real-time by the strength of the first target light TL1 to be measured. Further, as described above, such a method for monitoring a substrate utilizes optical emission spectroscopy (OES) using plasma light PL, without using an additional device, e.g., without using a probe or a blade. Accordingly, a method for monitoring a substrate capable of in-line monitoring in a non-destructive manner can be provided.

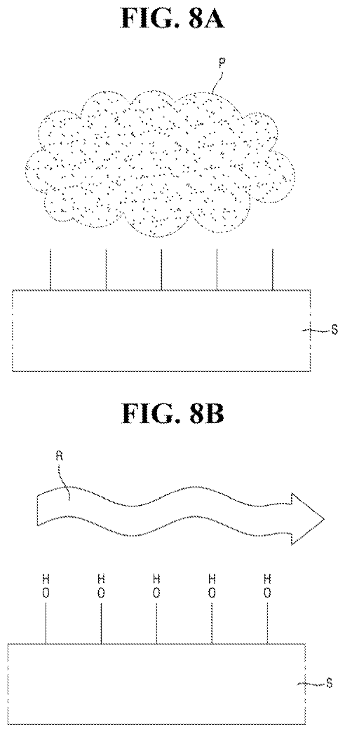

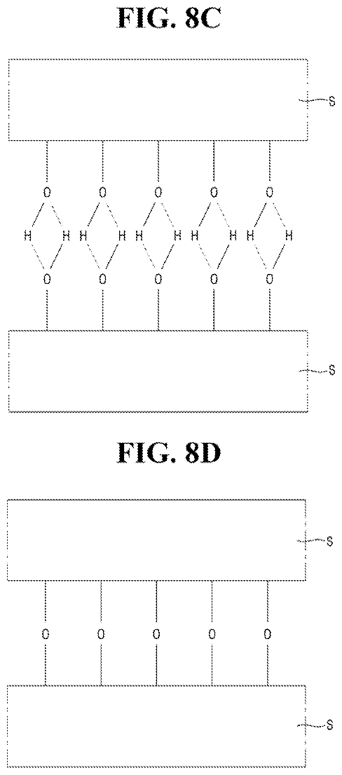

In the following description, the relationship between the plasma process on the substrate S and the bonding strength of the substrate S will be described referring to FIGS. 8A to 8D. FIGS. 8A to 8D are exemplary intermediate stage diagrams for explaining the bonding process on the substrate, e.g., bonding two substrates into a laminated structure by using plasma surface treatment (without using a bonding agent therebetween). For convenience of explanation, repeated parts of contents explained above using FIGS. 1 to 7 will be only briefly described or omitted.

Referring to FIG. 8A, in order to perform the bonding process on the substrate S, a surface treatment process on the substrate S is performed using the plasma P. The surface treatment process may be performed by, e.g., the substrate treatment system described above using FIGS. 1 and 2. As the surface treatment process is performed, e.g., plasma is applied to the surface of the substrate S, a dangling bond may be formed on the surface of the substrate S (e.g., with a high surface energy).

Next, referring to FIG. 8B, the cleaning process R on the substrate S is performed. The cleaning process R may be performed by, e.g., a spin coater. As the cleaning process R is performed, the surface of the substrate S may be cleaned. Further, as illustrated in FIG. 8B, as the cleaning process R is performed, the hydroxyl group (—OH) may be bonded to the dangling bond formed on the surface of the substrate S, e.g., as a result of interaction with a cleaning agent during the cleaning process R. In some embodiments, the cleaning process R may utilize deionized water (DI water).

Next, referring to FIG. 8C, a bonding process on the substrate S is performed. For example, two substrates S, each processed according to the steps described above using FIGS. 8A and 8B, may be bonded to each other. The substrates S to be bonded may form an initial bond by atoms bonded to the dangling bond at the bonding surface. For example, as illustrated in FIG. 8C, hydrogen bonds due to the hydroxyl group (—OH) may be formed on the facing bonding surfaces of the substrates S to be bonded.

Next, referring to FIG. 8D, the bonding process on the substrates S is completed. For example, an annealing process may be performed on the substrates S (which are bonded via hydrogen bonds described above with reference to FIG. 8C). As the annealing process is performed, a dehydration condensation reaction, in which water (H₂O) molecules are released from the bonding surface of the substrates S to be bonded, and degassing may occur. As a result, the substrates S to be bonded may form a strong bond due to a covalent bond.

As described above with respect to FIGS. 8A to 8D, the plasma process on the substrate S has a strong relationship with the bonding strength of the substrate S, e.g., the plasma process on the substrate S may impart a high bonding strength to the surface of the substrate S. Therefore, the bonding strength of the substrate S may be monitored by analyzing the plasma condition using optical emission spectroscopy (OES). As an example, as described above with reference to FIGS. 3 to 7, the bonding strength of the substrate S may be monitored by analyzing the strength of the first target light TL1 over time.

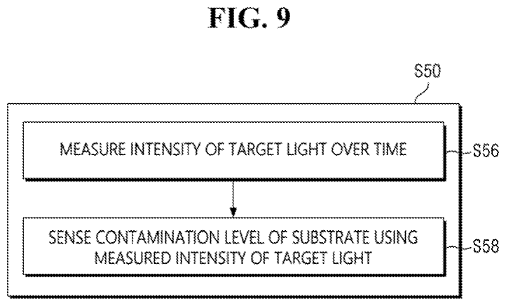

FIGS. 9 to 11 are diagrams for explaining a method for monitoring a substrate according to some embodiments. For the convenience of explanation, repeated parts of contents explained above using FIGS. 1 to 4 will be only briefly described or omitted.

Referring to FIGS. 3 and 9, in the method for monitoring a substrate according to some embodiments, monitoring the surface condition of the substrate S (S50) may include measuring the intensity of the target light over time (S56), and sensing the contamination level of the substrate S using the measured intensity of the target light (S58).

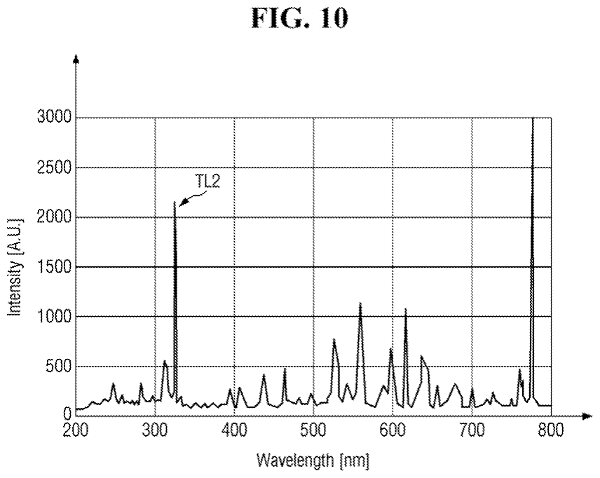

As an example, the emission spectrum of FIG. 10 may be provided from the spectrometer 500. Next, a second target light TL2 related to the contamination level of the substrate S may be selected from the emission spectrum of FIG. 10. That is, the second target light TL2 may be emitted light of a chemical species related to the contamination level of the substrate S. As an example, the second target light TL2 may be emitted light of a chemical species which causes contamination of the substrate S.

In some embodiments, the second target light TL2 may be emitted light of copper (Cu) selected from the plasma light PL. As an example, light having a wavelength of about 324 nm may be selected as the second target light TL2 from the emission spectrum of FIG. 10. However, this is only exemplary, and other emitted light related to the contamination level of the substrate S may be selected as the second target light TL2. Further, a plurality of emitted lights having different wavelengths may be selected as the second target light TL2.

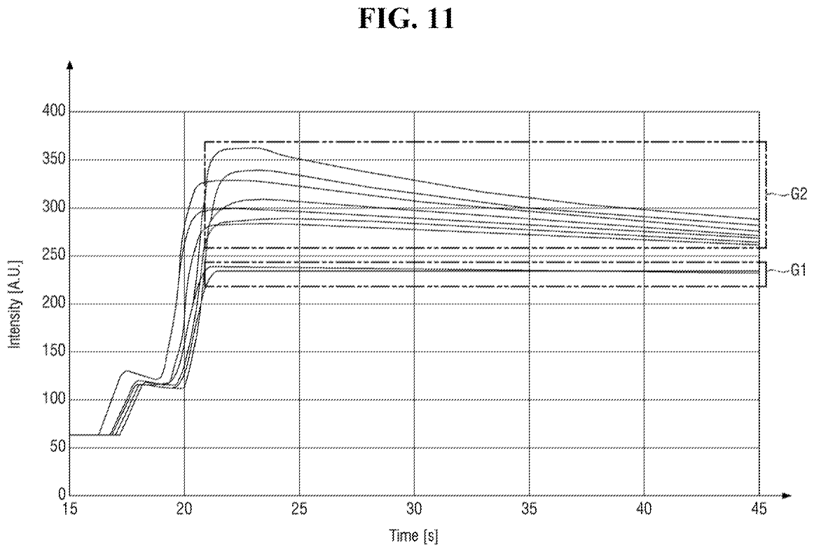

Subsequently, the intensity of the second target light TL2 over time may be measured (S56). As an example, the intensity of the second target light TL2 over time may be measured multiple times to provide the graph of FIG. 11.

Next, the contamination level of the substrate S may be sensed by utilizing the measured intensity of the second target light TL2 (S58). For example, it is possible to sense whether the measured intensity of the second target light TL2 exceeds a predetermined value. Accordingly, it is possible to determine whether the plasma process is normally performed on the substrate S. As an example, as shown in FIG. 11, group G1, in which the intensity of the second target light TL2 to be measured is about 250 or less, has a low contamination level of the substrate S and may be classified as a normal plasma process. As another example, group G2, in which the intensity of the second target light TL2 to be measured is about 250 or more, has a high contamination level of the substrate S and may be classified as an abnormal plasma process.

As the contamination level of the substrate S is sensed by the intensity of the second target light TL2 measured over time, the surface condition of the substrate S may be monitored in real-time. Further, as described above, such a method for monitoring a substrate utilizes optical emission spectroscopy (OES) using plasma light PL without using an additional device, e.g., without using a probe or a blade. Accordingly, it is possible to provide a method for monitoring a substrate capable of in-line monitoring in a non-destructive manner.

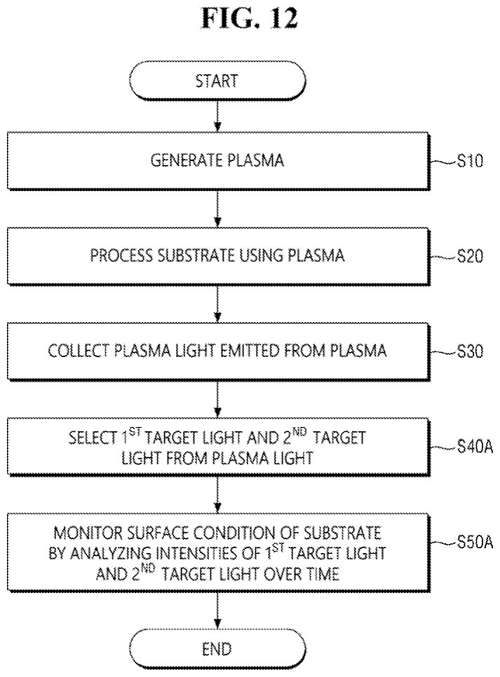

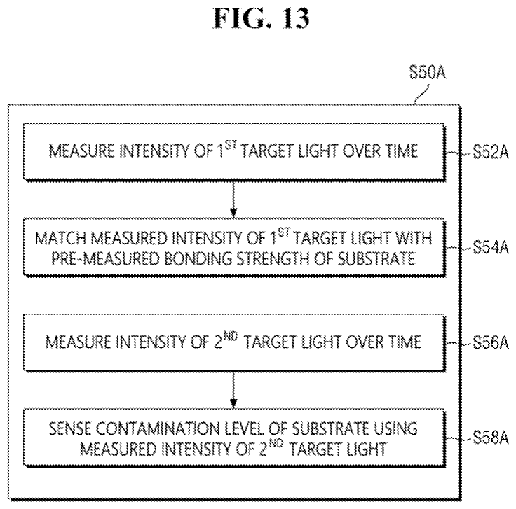

FIGS. 12 and 13 are diagrams for explaining a method for monitoring a substrate according to some embodiments. For the convenience of explanation, repeated parts of contents explained above using FIGS. 1 to 11 will be only briefly described or omitted.

Referring to FIGS. 12 and 13, the method for monitoring het substrate S according to some embodiments may include both analyzing the intensity of the first target light TL1 over time to monitor the surface condition of the substrate S, and analyzing the intensity of the target light TL2 over time to monitor the surface condition of the substrate S.

For example, the method for monitoring the substrate S according to some embodiments may include generating plasma P (S10), processing the substrate S using the plasma P (S20), receiving the plasma light PL emitted from plasma P (S30), selecting the first target light TL1 and the second target light TL2 from the plasma light PL (540A), and analyzing the intensity of the first target light TL1 and the intensity of the second target light TL2 over time to monitor the surface condition of the substrate S (550A).

Because generating the plasma P (S10), processing the substrate S using the plasma P (S20), and receiving the plasma light PL emitted from the plasma P (S30) are the same as those described above using FIG. 3, detailed description thereof will be omitted below.

Subsequently, the first target light TL1 related to the bonding strength of the substrate S and the second target light TL2 related to the contamination level of the substrate S may be selected (540A). Subsequently, the intensity of the first target light TL1 over time may be measured (S52A), and the intensity of the second target light TL2 over time may be measured (S56A). Subsequently, the measured intensity of the first target light TL1 may be matched with the pre-measured bonding strength of the substrate S (S54A), and the contamination level of the substrate S may be sensed using the measured intensity of the second target light TL2 (S58A). In some embodiments, analyzing the intensity of the first target light TL1 over time to monitor the surface condition of the substrate S may be performed at the same time as analyzing the intensity of the second target light TL2 over time to monitor the surface condition of the substrate S, e.g., monitoring the bonding strength of the substrate S and monitoring the contamination level of the substrate S may be performed simultaneously.

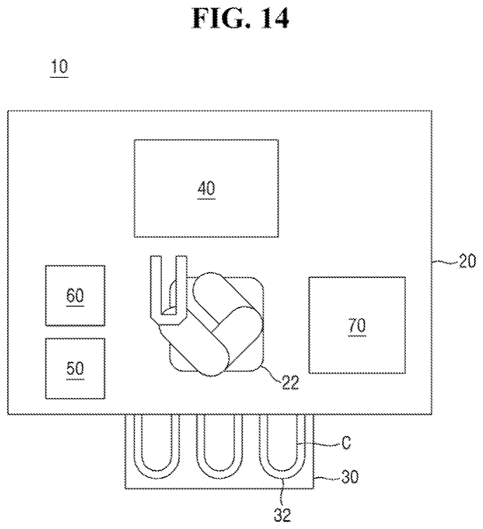

Hereinafter, a substrate processing system according to exemplary embodiments will be described referring to FIGS. 1 to 14. FIG. 14 is an exemplary diagram for explaining the substrate processing system according to some embodiments. For convenience of explanation, repeated parts of contents explained above using FIGS. 1 to 13 will be only briefly described or omitted.

Referring to FIG. 14, a substrate processing system 10 according to some embodiments may include a plasma processing device 40, a cleaning device 50, an alignment device 60, and a bonding device 70 placed inside a clean chamber 20. Further, the substrate processing system 10 may further include a cassette stage 30 provided on one side of the clean chamber 20.

In some embodiments, the clean chamber 20 may be made up of a rectangular parallelepiped chamber having an internal space, and may form a space in which fine dust and foreign matter are blocked to maintain a predetermined range of cleanliness.

The cassette stage 30 may provide a space in which the substrates S are stored. For example, a carrier C (e.g., front opening unified pod (FOUP)) capable of accommodating a plurality of substrates S may be supported on a support plate 32 of the cassette stage 30. The substrates S accommodated in the carrier C may be conveyed into the clean chamber 20 by a transfer robot 22. For example, the three carriers C may be placed on the cassette stage 30. The first and second carriers C may accommodate the first and second substrates S to be bonded to each other, and the third carrier C may accommodate the bonded substrates S.

In an example, circuits for an image sensor chip may be formed on the first substrate, and light-receiving sensors for the image sensor chip may be formed on the second substrate. In another example, circuits for a semiconductor package, e.g., such as a high bandwidth memory (HBM), may be formed on the first substrate, and memory devices for the semiconductor package may be formed on the second substrate.

The plasma processing device 40 may generate plasma P and perform the plasma process on the surface of the substrate S. For example, the plasma processing device 40 may include the substrate processing system described above using FIGS. 1 and 2. The plasma P generated by the plasma processing device 40 may be, e.g., inductively coupled plasma, capacitively coupled plasma, or microwave plasma.

The cleaning device 50 may clean the substrate S that is subjected to surface treatment by the plasma processing device 40. In some embodiments, the cleaning device 50 may coat the surface of the substrate S with deionized water (DI water) using the spin coater. Such ultrapure water not only cleans the surface of the substrate S, but also allows the hydroxyl group (—OH) to be satisfactorily bonded to the surface of the substrate S.

The alignment device 60 may sense a flat portion (or a notch) of the substrate S to align the substrate S. The substrate S aligned by the alignment device 60 may be conveyed to the bonding device 70 by the transfer robot 22. The alignment device 60 may be provided as a loading unit for loading the aligned substrate S into the bonding device 70. The bonding device 70 may adsorb the substrates S loaded from the alignment device 60 and bond them to each other. In some embodiments, at least one of the alignment device 60 and the bonding device 70 may include a heating device that performs a local heat treatment on the substrate S for a temperature dispersion control of the substrate S.

Hereinafter, a method for fabricating a semiconductor device according to an exemplary embodiment will be described referring to FIGS. 1 to 16c.

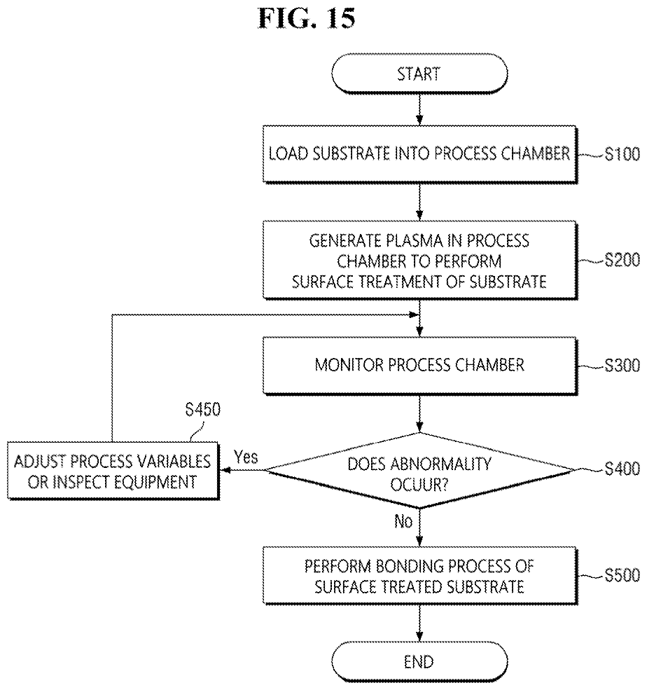

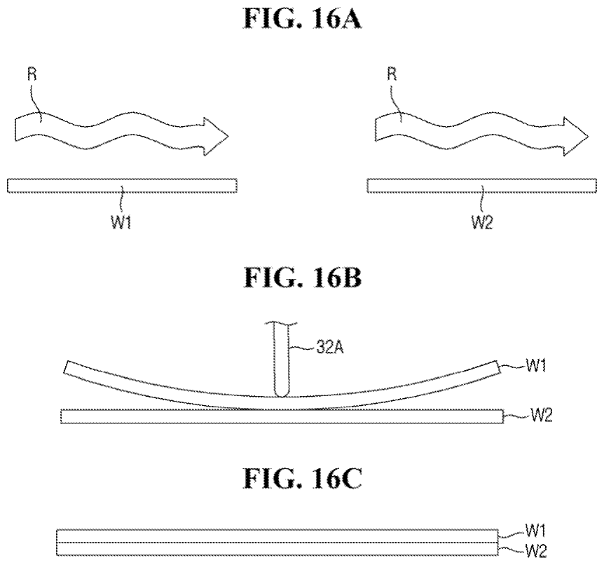

FIGS. 15 to 16c are diagrams for explaining a method for fabricating a semiconductor device using the method for monitoring the substrate according to some embodiments. For the convenience of explanation, repeated parts of contents explained above using FIGS. 1 to 13 will be only briefly described or omitted.

Referring to FIGS. 1, 2 and 15, first, the substrate S may be loaded into the process chamber 100 (S100). The substrate S may be, e.g., a wafer. The substrate S may include a fine pattern formed to realize a semiconductor device. In some embodiments, the fine pattern may include conductive materials, e.g., metal, metal nitride, metal silicide, and metal silicide nitride film. In some other embodiments, the fine pattern may include insulating materials, e.g., silicon oxide, silicon nitride, and silicon oxynitride. In yet some other embodiments, the fine pattern may include semiconductor materials, e.g., polysilicon.

Subsequently, the plasma P may be generated in the process chamber 100 to perform surface treatment on the substrate S (S200). For example, the surface treatment process described above using FIG. 8A may be performed. As the surface treatment process is performed, a dangling bond may be formed on the surface of the substrate S.

Subsequently, the process chamber 100 may be monitored (S300). For example, monitoring of the process chamber 100 (S300) may utilize the method for monitoring a substrate described above with reference to FIGS. 3 to 13. For example, monitoring the process chamber 100 (S300) may include receiving the plasma light PL emitted from the plasma P (S30), selecting the first target light TL1 and the second target light TL2 from the plasma light PL (S40), and analyzing the intensity of the first target light TL1 and the intensity of the second target light TL2 over time to monitor the surface condition of the substrate S (S50).

Subsequently, it may be determined whether an abnormality has occurred in the plasma process performed in the process chamber 100 (S400). For example, determining whether an abnormality has occurred in the plasma process (S400) may be based on the surface condition of the substrate S to be monitored. As an example, when the intensity of the first target light TL1 to be measured does not reach a predetermined value, it may be determined that the bonding strength of the substrate S is insufficient and an abnormality occurs in the plasma process. As another example, when the intensity of the second target light TL2 to be measured exceeds a predetermined value, it may be determined that the contamination level of the substrate S is high and an abnormality occurs in the plasma process.

When it is determined that an abnormality occurs in the plasma process performed in the process chamber 100, the process variables of the plasma process may be adjusted or the equipment may be inspected (S450). For example, the process variables may include the impedance of the matching unit 300, the pressure of the process gas supplied into the process chamber 100, the temperature in the process chamber 100, and the like. For example, inspection of the equipment may include performing preventive maintenance (PM). The preventive maintenance may include grasping the deterioration condition through the hardware diagnosis of equipment (e.g., the shower head 130) of the above-mentioned substrate processing system, and determining the maintenance time and the maintenance method.

For example, as illustrated in FIG. 15, monitoring of the process chamber 100 (S300) and determining whether an abnormality has occurred in the plasma process (S400) may be repeated until it is in determined that no abnormalities exist in the plasma process. Therefore, the method for monitoring a substrate according to some embodiments may be utilized for fault detection and classification (FDC) of the plasma process.

When it is determined that no abnormality occurs in the plasma process performed in the process chamber 100, a bonding process may be performed on the surface-treated substrate S (S500). The bonding process on the substrate S will be described hereinafter with reference to FIGS. 16A-16C.

FIGS. 16A to 16C are schematic intermediate stage diagrams for explaining the bonding process on the substrate S.

Referring to FIG. 16A, the cleaning process R may be performed on the first wafer W1 and the second wafer W2. The first wafer W1 and the second wafer W2 may each be the substrate S that is subjected to surface treatment by plasma treatment. For example, the first wafer W1 and the second wafer W2 may each be the substrate S that is subjected to surface treatment by the plasma processing device 40 of FIG. 14. For example, the cleaning process R may be performed by the cleaning device 50 of FIG. 14 (after completion of the plasma treatment). As the cleaning process R is performed, the surface of the first wafer W1 and the surface of the second wafer W2 may be cleaned.

Referring to FIG. 16B, the first wafer W1 and the second wafer W2 may be bonded to each other. For example, the first wafer W1 and the second wafer W2 may be bonded by the bonding device 70 of FIG. 14. As an example, a push rod 32A may be lowered to press a central portion of the first wafer W1 toward the second wafer W2. After that, the first wafer W1 deformed by the push rod 32A may be brought into contact with the second wafer W2. As a result, bonding may be started from the central portion of the first wafer W1.

Referring to FIG. 16C, the bonding process on the first wafer W1 and the second wafer W2 may be completed. In some embodiments, the annealing process may be performed. Therefore, the first wafer W1 and the second wafer W2 to be bonded may form a strong bond by a covalent bond.

Although the method for fabricating the semiconductor device described in FIGS. 16A to 16C has been described on the basis of the wafer bonding process, this is merely an example. As another example, the method for fabricating the semiconductor device according to some embodiments may be applicable to various bonding processes, e.g., a die-to-wafer bonding process and a die-to-die bonding process.

By way of summation and review, aspects of embodiments provide a method for monitoring a substrate capable of in-line monitoring in a non-destructive manner. Aspects of embodiments also provide a method for fabricating a semiconductor device using the method for monitoring the substrate capable of in-line monitoring in a non-destructive manner. Aspects of embodiments also provide a substrate processing system using the method for monitoring the substrate capable of in-line monitoring in a non-destructive manner.

That is, an intensity of a target light related to the surface condition of the substrate may be measured. As the intensity of the target light measured over time is matched with the bonding strength of the substrate measured in advance, the surface condition of the substrate can be monitored in real-time. Further, optical emission spectroscopy (OES) using plasma light, without an additional device (e.g., without a probe or a blade), may be used, thereby providing a method for monitoring a substrate capable of in-line monitoring in a non-destructive manner.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method for fabricating a semiconductor device, the method comprising:
loading a substrate into a process chamber;
processing the substrate in the process chamber, using a plasma generated inside the process chamber;
receiving a plasma light emitted from the plasma;
selecting a target light from the plasma light, such that the target light is related to a surface condition of the substrate; and
analyzing an intensity of the target light over time to monitor the surface condition of the substrate.

2. The method for fabricating the semiconductor device as claimed in claim 1, wherein selecting the target light includes selecting an emitted light of a chemical species related to the surface condition of the substrate from an emission spectrum generated from the plasma light.

3. The method for fabricating the semiconductor device as claimed in claim 1, wherein monitoring the surface condition of the substrate includes:
measuring the intensity of the target light over time; and
matching the measured intensity of the target light with a pre-measured bonding strength of the substrate.

4. The method for fabricating the semiconductor device as claimed in claim 3, wherein the target light is an emitted light of a hydroxyl radical selected from the plasma light.

5. The method for fabricating the semiconductor device as claimed in claim 1, wherein monitoring the surface condition of the substrate includes:
measuring the intensity of the target light over time; and
sensing a contamination level of the substrate, using the measured intensity of the target light.

6. The method for fabricating the semiconductor device as claimed in claim 5, wherein sensing the contamination level of the substrate includes sensing whether the measured intensity of the target light exceeds a predetermined value.

7. The method for fabricating the semiconductor device as claimed in claim 5, wherein the target light is an emitted light of copper selected from the plasma light.

8. The method for fabricating the semiconductor device as claimed in claim 1, further comprising adjusting process variables of the substrate based on the surface condition of the substrate to be monitored.

9. A method for fabricating a semiconductor device, the method comprising:
loading a substrate into a process chamber;
performing a surface treatment on the substrate in the process chamber, using a plasma generated inside the process chamber;
receiving a plasma light emitted from the plasma;
selecting a first target light from the plasma light, such that the first target light is related to a bonding strength of the substrate;
measuring an intensity of the first target light over time to monitor the bonding strength of the substrate; and
performing a bonding process on the substrate, after completing the surface treatment on the substrate.

10. The method for fabricating the semiconductor device as claimed in claim 9, further comprising adjusting process variables of the substrate based on the bonding strength of the substrate to be monitored.

11. The method for fabricating the semiconductor device as claimed in claim 9, wherein performing the bonding process includes:
providing a first wafer and a second wafer, such that each of the first wafer and the second wafer is the substrate after completing the surface treatment;
performing a cleaning process on a bonding surface of each of the first wafer and the second wafer; and
bonding the bonding surface of the first wafer and the bonding surface of the second wafer.

12. The method for fabricating the semiconductor device as claimed in claim 11, wherein the cleaning process includes using deionized water.

13. The method for fabricating the semiconductor device as claimed in claim 9, wherein the first target light includes an emitted light of hydroxyl radical selected from the plasma light.

14. The method for fabricating the semiconductor device as claimed in claim 9, further comprising:
selecting a second target light from the plasma light, such that the second target light is related to a contamination level of the substrate; and
measuring an intensity of the second target light over time to monitor the contamination level of the substrate.

15. The method for fabricating the semiconductor device as claimed in claim 14, wherein monitoring the bonding strength of the substrate and monitoring the contamination level of the substrate are performed at the same time.

16. The method for fabricating the semiconductor device as claimed in claim 14, wherein the second target light includes an emitted light of copper selected from the plasma light.

17. A method for fabricating a semiconductor device, the method comprising:
providing a substrate; and
performing a plasma process on the substrate using a substrate processing system,
wherein the substrate processing system includes:
a process chamber into which the substrate is loaded;
a spectrometer which receives a plasma light generated from a plasma; and
an analyzer which receives data about the plasma light from the spectrometer, the analyzer being configured to monitor a surface condition of the substrate,
wherein the analyzer is configured to select a target light related to the surface condition of the substrate from the data about the plasma light, and to analyze an intensity of the target light over time to monitor the surface condition of the substrate.

18. The method for fabricating the semiconductor device as claimed in claim 17, wherein:
the spectrometer is configured to generate an emission spectrum from the plasma light, and
the analyzer is configured to select an emitted light of a chemical species related to the surface condition of the substrate as the target light, from the emission spectrum.

19. The method for fabricating the semiconductor device as claimed in claim 17, wherein the analyzer is configured to measure the intensity of the target light over time, and to match the measured intensity of the target light with a pre-measured bonding strength of the substrate.

20. The method for fabricating the semiconductor device as claimed in claim 17, wherein the analyzer is configured to measure the intensity of the target light over time, and to sense a contamination level of the substrate, using the measured intensity of the target light.
